(19) United States
(12) Patent Application Publication
(10) Pub. No.: US 2016/0065195 A1
(43) Pub. Date: Mar. 3, 2016

(54) MULTIPHASE OSCILLATING SIGNAL GENERATION AND ACCURATE FAST FREQUENCY ESTIMATION

(71) Applicant: QUALCOMM Incorporated, San Diego, CA (US)

(72) Inventors: Mohammad FARAZIAN, San Diego, CA (US); Serkan SAYILIR, Bingol (TR); Marco ZANUSO, San Diego, CA (US); Yiwu TANG, San Diego, CA (US)

(21) Appl. No.: 14/471,530

(22) Filed: Aug. 28, 2014

(51) Int. Cl. H03K 5/15; H03H 11/22; H03H 11/20

(52) U.S. Cl. CPC H03K 5/1506; H03H 11/20; H03H 11/22; H03K 2005/00286

(57) ABSTRACT

Certain aspects of the present disclosure provide methods and apparatus for generating multiple oscillating signals having different phases. One example multiphase generating circuit generally includes a first phase shifting circuit configured to phase shift an input signal having an input frequency, such that an output signal of the first phase shifting circuit has a first phase difference with respect to the input signal; a first frequency dividing circuit configured to receive the input signal and output a first set of signals having a first frequency less than the input frequency of the input signal; and a second frequency dividing circuit configured to receive the output signal of the first phase shifting circuit and output a second set of signals having a second frequency less than the input frequency of the input signal. The multiphase signals may be used for fast frequency estimation of the input signal or in N-path filters.

### TECHNICAL FIELD

Certain aspects of the present disclosure generally relate to radio frequency (RF) electronic circuits and, more particularly, to generating multiple oscillating signals having different phases.

### BACKGROUND

Wireless communication networks are widely deployed to provide various communication services such as telephony, video, data, messaging, broadcasts, and so on. Such networks, which are usually multiple access networks, support communications for multiple users by sharing the available network resources. For example, one network may be a 3G (the third generation of mobile phone standards and technology) system, which may provide network service via any one of various 3G radio access technologies (RATs) including EVDO (Evolution-Data Optimized), 1×RTT (1 times Radio Transmission Technology, or simply 1×), W-CDMA (Wideband Code Division Multiple Access), UMTS-TDD (Universal Mobile Telecommunications System-Time Division Duplexing), HSPA (High Speed Packet Access), GPRS (General Packet Radio Service), or EDGE (Enhanced Data rates for Global Evolution). The 3G network is a wide area cellular telephone network that evolved to incorporate high-speed internet access and video telephony, in addition to voice calls. Furthermore, a 3G network may be more established and provide larger coverage areas than other network systems. Such multiple access networks may also include code division multiple access (CDMA) systems, time division multiple access (TDMA) systems, frequency division multiple access (FDMA) systems, orthogonal frequency division multiple access (OFDMA) systems, single-carrier FDMA (SC-FDMA) networks, 3rd Generation Partnership Project (3GPP) Long Term Evolution (LTE) networks, and Long Term Evolution Advanced (LTE-A) networks.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station.

### SUMMARY

Certain aspects of the present disclosure generally relate to generating multiple oscillating signals having different phases (i.e., multiphase oscillating signal generation).

Certain aspects of the present disclosure provide a multiphase generating circuit. The circuit generally includes a first phase shifting circuit configured to phase shift an input signal having an input frequency, such that an output signal of the first phase shifting circuit has a first phase difference with respect to the input signal; a first frequency dividing circuit configured to receive the input signal and output a first set of signals having a first frequency less than the input frequency of the input signal; and a second frequency dividing circuit configured to receive the output signal of the first phase shifting circuit and output a second set of signals having a second frequency less than the input frequency of the input signal.

According to certain aspects, the first frequency equals the second frequency. The first frequency and the second frequency may both be half the input frequency.

According to certain aspects, the first phase shifting circuit comprises a delay line. For certain aspects, the delay line is adjustable, such that the first phase difference is a variable phase difference with respect to the input signal.

According to certain aspects, at least one of the first frequency dividing circuit or the second frequency dividing circuit includes a frequency divide-by-2 circuit.

According to certain aspects, signals in the first set have phase differences of 0°, 90°, 180°, and 270° with respect to a reference signal. The reference signal is one of the first set of signals. In this case, signals in the second set may have phase differences of 45°, 135°, 225°, and 315° with respect to the reference signal.

According to certain aspects, the multiphase generating circuit is an 8-phase generating circuit. In other aspects, the multiphase generating circuit is a 16-phase generating circuit.

According to certain aspects, the input signal is a voltage-controlled oscillator (VCO) signal.

According to certain aspects, the input signal is a differential signal having a positive signal and a negative signal. For certain aspects, the first phase shifting circuit is configured to phase shift the negative signal. For other aspects, the phase shifting circuit is configured to phase shift the positive signal.

According to certain aspects, the multiphase generating circuit further includes a second phase shifting circuit configured to phase shift the output signal of the first phase shifting circuit, such that an output signal of the second phase shifting circuit has a second phase difference with respect to the output signal of the first phase shifting circuit. For certain aspects, the second phase shifting circuit comprises an adjustable delay line, such that the second phase difference is a variable phase difference with respect to the output signal of the first phase shifting circuit. The second phase difference may be nominally 90°. A sum of the first phase difference and the second phase difference may be nominally 180°.

For certain aspects, the multiphase generating circuit further includes a calibration circuit configured to receive the input signal and the output signal of the second phase shifting circuit and to adjust at least one of the first or second phase difference based on relative timing of the input signal and the output signal of the second phase shifting circuit. The calibration circuit may include a phase comparator and a finite state machine. The phase comparator may be configured to compare edges of the input signal with edges of the output signal of the second phase shifting circuit; and to output a comparison signal indicating whether the edges of the input signal are earlier or later than the edges of the output signal of the second phase shifting circuit. The finite state machine may be configured to receive the comparison signal and to control increasing or decreasing a parameter affecting the at least one of the first or second phase difference based on the comparison signal.

According to certain aspects, the first phase difference is nominally 90°.

According to certain aspects, the multiphase generating circuit further includes a second phase shifting circuit configured to phase shift the output signal of the first phase shifting circuit, such that an output signal of the second phase shifting circuit has a second phase difference with respect to the output signal of the first phase shifting circuit; and a third frequency dividing circuit configured to receive the output signal of the second phase shifting circuit and output a third set of signals having a third frequency less than the input frequency of the input signal. For certain aspects, the multiphase generating circuit further includes a third phase shifting circuit configured to phase shift the output signal of the second phase shifting circuit, such that an output signal of the third phase shifting circuit has a third phase difference with respect to the output signal of the second phase shifting circuit; and a fourth frequency dividing circuit configured to receive the output signal of the third phase shifting circuit and output a fourth set of signals having a fourth frequency less than the input frequency of the input signal.

According to certain aspects, the multiphase generating circuit further includes a fourth phase shifting circuit configured to phase shift the output signal of the third phase shifting circuit, such that an output signal of the fourth phase shifting circuit has a fourth phase difference with respect to the output signal of the third phase shifting circuit. The fourth phase difference may nominally be 90°. For certain aspects, the fourth phase shifting circuit is an adjustable delay line, such that the fourth phase difference is a variable phase difference with respect to the output signal of the third phase shifting circuit. A sum of the first phase difference, the second phase difference, the third phase difference, and the fourth phase difference may nominally be 180°.

Certain aspects of the present disclosure provide a method for multiphase signal generation. The method generally includes frequency dividing an input signal to generate a first set of signals having a first frequency less than an input frequency of the input signal; phase shifting the input signal to produce a first output signal having a first phase difference with respect to the input signal; and frequency dividing the first output signal to generate a second set of signals having a second frequency less than the input frequency.

Certain aspects of the present disclosure provide an apparatus for multiphase signal generation. The apparatus generally includes means for frequency dividing an input signal to generate a first set of signals having a first frequency less than an input frequency of the input signal; means for phase shifting the input signal to produce a first output signal having a first phase difference with respect to the input signal; and means for frequency dividing the first output signal to generate a second set of signals having a second frequency less than the input frequency.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates an example wireless communications network in accordance with certain aspects of the present disclosure.

FIG. 2 is a block diagram of an example access point (AP) and user terminals in accordance with certain aspects of the present disclosure.

FIG. 3 is a block diagram of an example transceiver front end in accordance with certain aspects of the present disclosure.

FIG. 4A is a block diagram of an example 8-phase signal generating circuit, in accordance with certain aspects of the present disclosure.

FIG. 4B is a block diagram of an example 16-phase signal generating circuit, in accordance with certain aspects of the present disclosure.

FIG. 5 is a block diagram of an example 8-phase signal generating circuit and an example calibration circuit for calibrating one or more variable delay lines in the 8-phase signal generating circuit, in accordance with certain aspects of the present disclosure.

FIG. 6 is a flow diagram of example operations for multiphase signal generation, in accordance with certain aspects of the present disclosure.

FIG. 7 adds a plurality of frequency counters and a summer to the circuit of FIG. 4A for fast frequency estimation, in accordance with certain aspects of the present disclosure.

FIG. 8 is a block diagram of an example N-path filter using multiphase oscillating signals generated by a multiphase signal generating circuit, in accordance with certain aspects of the present disclosure.

### DETAILED DESCRIPTION

Various aspects of the present disclosure are described below. It should be apparent that the teachings herein may be embodied in a wide variety of forms and that any specific structure, function, or both being disclosed herein is merely representative. Based on the teachings herein, one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. Furthermore, an aspect may comprise at least one element of a claim.

The word “exemplary” is used herein to mean “serving as an example, instance, or illustration.” Any aspect described herein as “exemplary” is not necessarily to be construed as preferred or advantageous over other aspects.

The techniques described herein may be used in combination with various wireless technologies such as Code Division Multiple Access (CDMA), Orthogonal Frequency Division Multiplexing (OFDM), Time Division Multiple Access (TDMA), Spatial Division Multiple Access (SDMA), Single Carrier Frequency Division Multiple Access (SC-FDMA), Time Division Synchronous Code Division Multiple Access (TD-SCDMA), and the like. Multiple user terminals can concurrently transmit/receive data via different (1) orthogonal code channels for CDMA, (2) time slots for TDMA, or (3) sub-bands for OFDM. A CDMA system may implement IS-2000, IS-95, IS-856, Wideband-CDMA (W-CDMA), or some other standards. An OFDM system may implement Institute of Electrical and Electronics Engineers (IEEE) 802.11 (Wireless Local Area Network (WLAN)), IEEE 802.16 (Worldwide Interoperability for Microwave Access (WiMAX)), Long Term Evolution (LTE) (e.g., in TDD and/or FDD modes), or some other standards. A TDMA system may implement Global System for Mobile Communications (GSM) or some other standards. These various standards are known in the art. The techniques described herein may also be implemented in any of various other suitable wireless systems using radio frequency (RF) technology, including Global Navigation Satellite System (GNSS), Bluetooth, IEEE 802.15 (Wireless Personal Area Network (WPAN)), Near Field Communication (NFC), Small Cell, Frequency Modulation (FM), and the like.

### An Example Wireless System

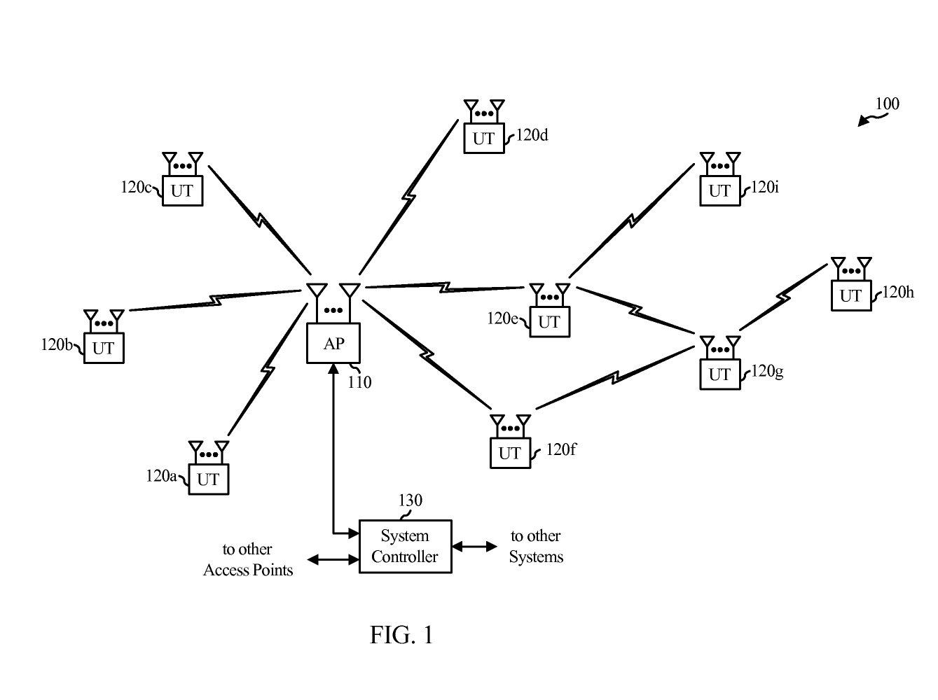

FIG. 1 illustrates a wireless communications system 100 with access points and user terminals. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

System 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≧1). The Nᵤ selected user terminals can have the same or different number of antennas.

Wireless system 100 may be a time division duplex (TDD) system or a frequency division duplex (FDD) system. For a TDD system, the downlink and uplink may share the same frequency band. For an FDD system, the downlink and uplink use different frequency bands. System 100 may also utilize a single carrier or multiple carriers for transmission. Each user terminal may be equipped with a single antenna (e.g., in order to keep costs down) or multiple antennas (e.g., where the additional cost can be supported).

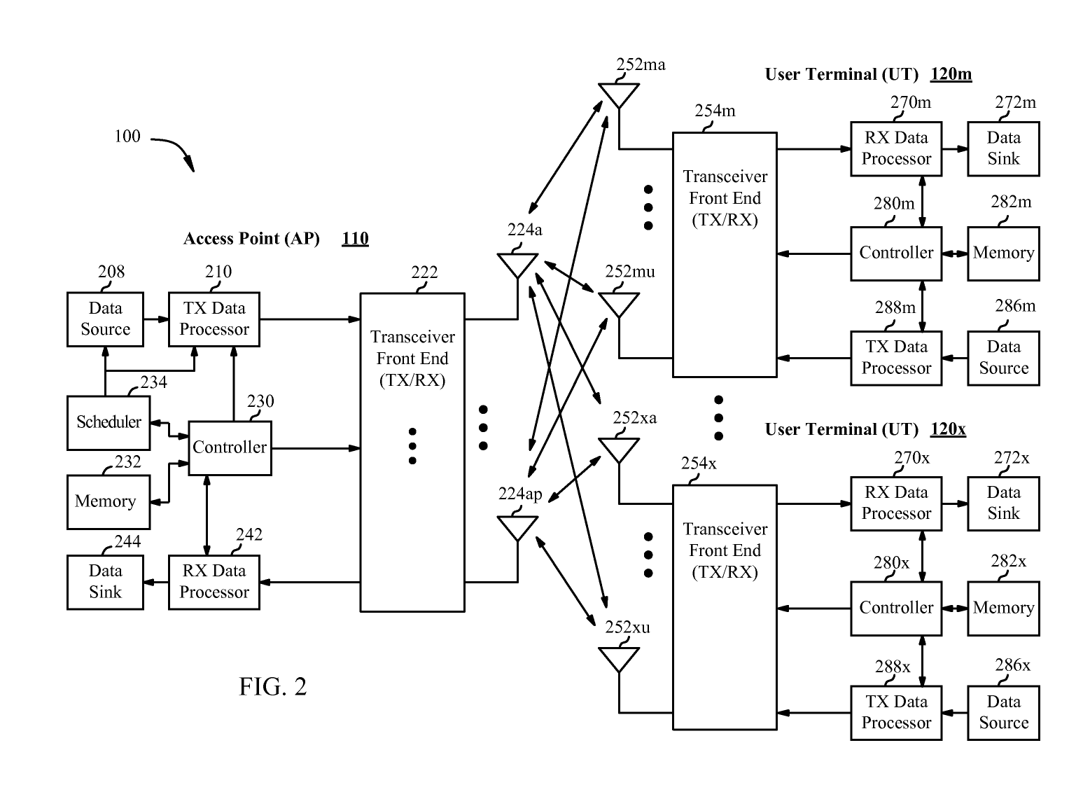

FIG. 2 shows a block diagram of access point 110 and two user terminals 120m and 120x in wireless system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point and user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254.

A number Nᵤₚ of user terminals may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. For certain aspects of the present disclosure, a combination of the signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222.

At each user terminal 120, N_{ut,m} antennas 252 receive the downlink signals from access point 110. For receive diversity at the user terminal 120, the transceiver front end 254 may select signals received from one of the antennas 252 for processing. For certain aspects of the present disclosure, a combination of the signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

Those skilled in the art will recognize the techniques described herein may be generally applied in systems utilizing any type of multiple access schemes, such as TDMA, SDMA, Orthogonal Frequency Division Multiple Access (OFDMA), CDMA, SC-FDMA, and combinations thereof.

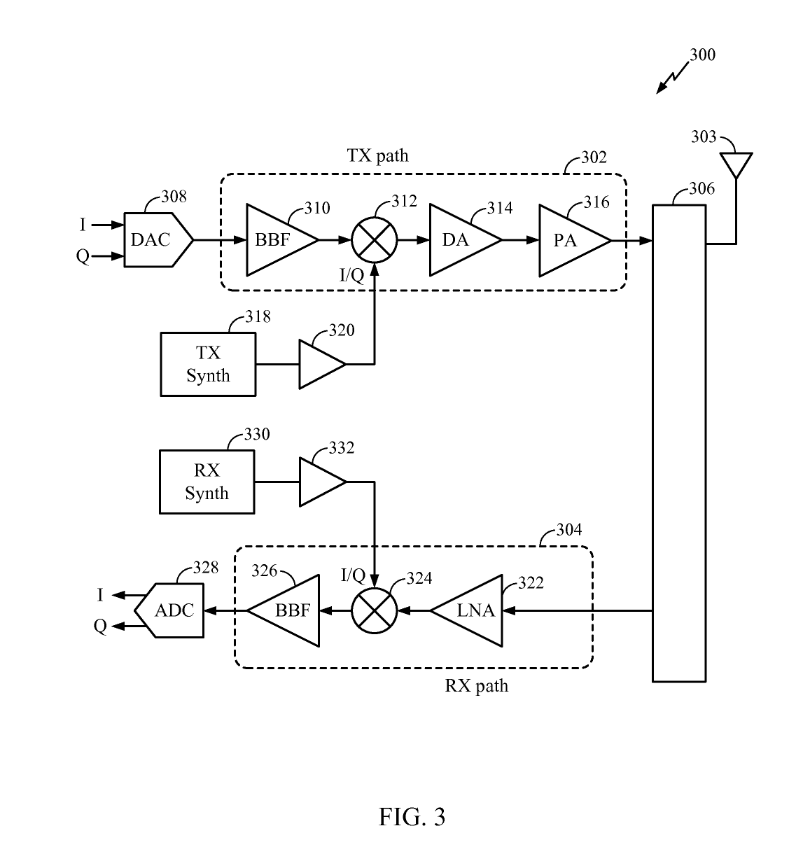

FIG. 3 is a block diagram of an example transceiver front end 300, such as transceiver front ends 222, 254 in FIG. 2, in accordance with certain aspects of the present disclosure. The transceiver front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier 316. The BBF 310, the mixer 312, and the DA 314 may be included in a radio frequency integrated circuit (RFIC), while the PA 316 is often external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which are amplified by the DA 314 and by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

While it is desirable for the output of an LO to remain stable in frequency, tuning to different frequencies indicates using a variable-frequency oscillator, which involves compromises between stability and tunability. Contemporary systems employ frequency synthesizers with a voltage-controlled oscillator (VCO) to generate a stable, tunable LO with a particular tuning range. Thus, the transmit LO is typically produced by a TX frequency synthesizer 318, which may be buffered or amplified by amplifier 320 before being mixed with the baseband signals in the mixer 312. Similarly, the receive LO is typically produced by an RX frequency synthesizer 330, which may be buffered or amplified by amplifier 332 before being mixed with the RF signals in the mixer 324.

### Example Multiphase Signal Generation

Generation of multiple phases of the VCO or LO signals has many useful applications, such as in N-path filtering or fast frequency measurement of the VCO or LO. Multiple oscillating signals having different phases (i.e., multiphase oscillating signals) may be generated using a ring-oscillator (e.g., in an injection-locked frequency divider (ILFD)). However, the obtainable phase noise (e.g., integrated phase noise (IPN)) is not sufficient for most wireless applications. Furthermore, a ring-oscillator may take up significant circuit area, which may not be available in some designs. Another approach to multiphase signal generation involves using cascaded frequency dividers, where particular outputs of one stage are used in the next stage of frequency dividers. With this approach, however, the multiphase signals are generally at a much lower frequency than the input signal, depending on the number of divider stages. Thus, the obtainable frequency limits the applications for this approach.

Accordingly, what is needed are techniques and apparatus for multiphase signal generation with reduced phase noise, decreased circuit area, and/or higher frequency compared to conventional approaches.

Certain aspects of the present disclosure provide for multiphase signal generation using one or more phase shifters and two or more frequency dividers to generate 8 or more multiphase signals. The multiphase signals operate with a frequency one half that of the input oscillating signal frequency (f_{VCO}). In this manner, the frequency of the input oscillating signal may be effectively measured at least four times faster (4f_{VCO}) than using a single phase of the input signal.

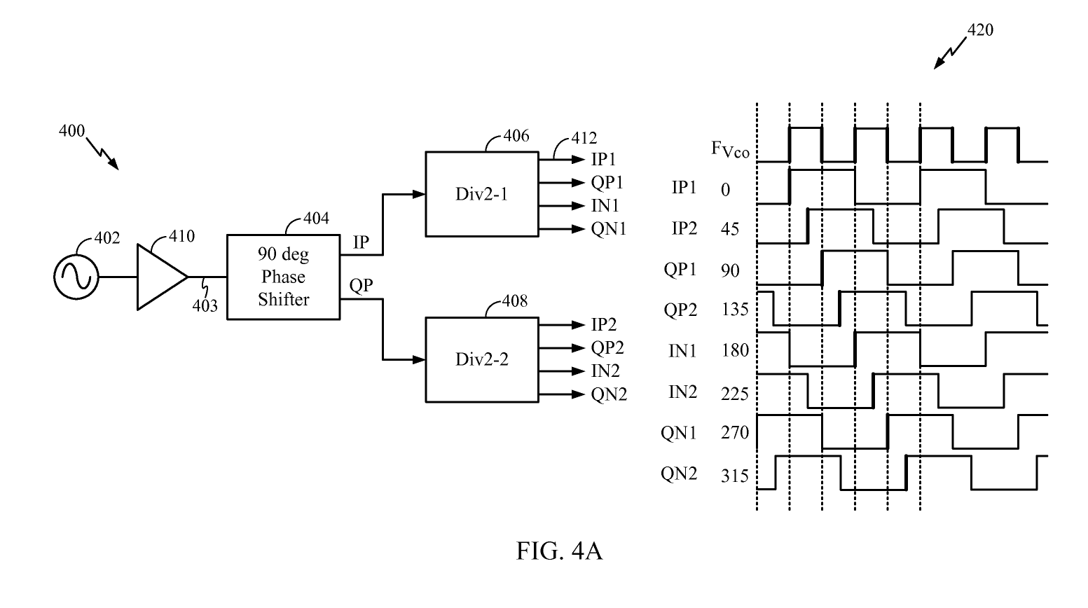

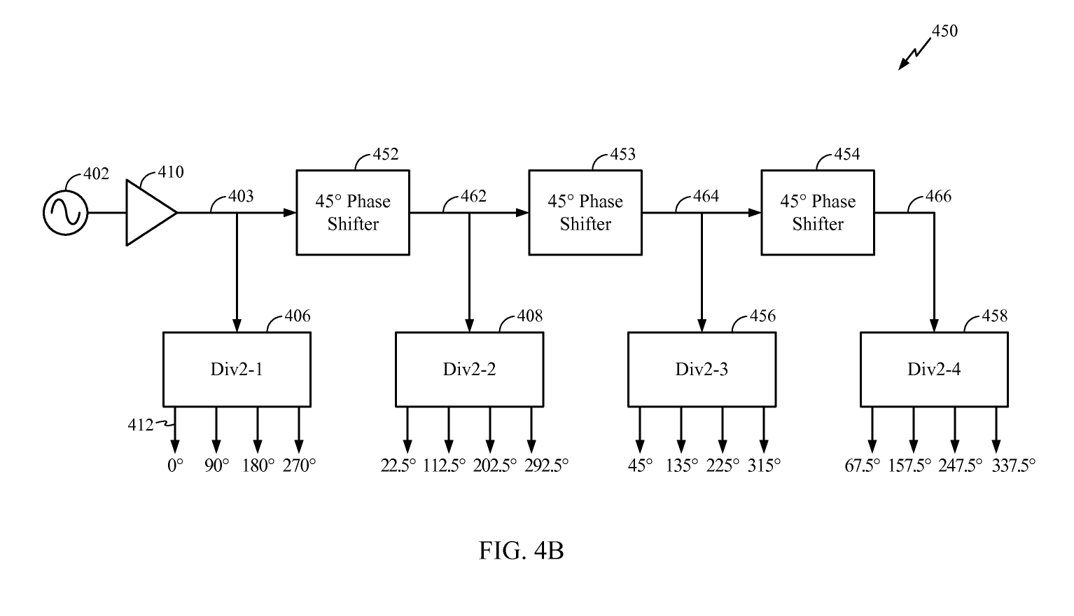

FIG. 4A is a block diagram of an example 8-phase signal generating circuit 400 and a corresponding timing diagram 420, in accordance with certain aspects of the present disclosure. The circuit 400 includes an input signal generator 402, a phase shifter 404, and two divide-by-2 (Div2) frequency dividers 406, 408.

The input signal generator 402 may be configured to generate an input oscillating signal, such as the output signal of a voltage-controlled oscillator (VCO) or a local oscillator (LO). For example, the input oscillating signal may be generated by the TX frequency synthesizer 318 or the RX frequency synthesizer 330 of FIG. 3. The input signal has a particular input frequency, which is referred to herein as f_{VCO}, even if the input signal is not produced by a VCO.

The phase shifter 404 may be configured to shift the phase of the input signal 403 received from the input signal generator 402 by about 90° nominally. This quadrature shift produces a quadrature (Q) signal (labeled “QP” for quadrature positive) from the input signal 403, which is considered as the in-phase (I) signal (labeled “IP” for in-phase positive). The phase shifter 404 may be implemented with a delay line to produce the 90° phase shift. For certain aspects, the delay line may be calibrated to account for any phase error away from 90°. For other aspects, the delay line may be adjustable, such that the phase shift may be tuned within a certain range. In this case, the variable delay line may also be calibrated to achieve the desired phase shift in the phase shifter 404.

The input signal (IP) is sent to a first divide-by-2 frequency divider 406 (labeled “Div2-1”), which produces a first set of four signals (IP1, QP1, IN1, and QN1) having a frequency one half that of the input signal (f_{VCO}/2), as shown in the timing diagram 420. The four signals in the first set have different phase differences therebetween. If the in-phase positive signal (IP1) output by the first frequency divider 406 is arbitrarily chosen as a phase reference signal 412 having a phase difference of 0°, then the first divider's quadrature positive signal (QP1) has a phase difference of 90° with respect to IP1 as depicted in the timing diagram 420. Likewise, the first divider's in-phase negative signal (IN1) has a phase difference of 180° with respect to IP1, and the first divider's quadrature negative signal (QN1) has a phase difference of 270° with respect to IP1.

The quadrature signal (QP) output by the phase shifter 404 is sent to a second divide-by-2 frequency divider 408 (labeled “Div2-2”), which produces a second set of four signals (IP2, QP2, IN2, and QN2) also having a frequency of f_{VCO}/2. The four signals in the second set have different phase differences therebetween, as well as from the signals in the first set due to the initial phase shift by the phase shifter 404. With IP1 output by the first frequency divider 406 remaining as the phase reference signal 412, then the second frequency divider's in-phase positive signal (IP2) has a phase difference of 45° with respect to IP1. Likewise, the second divider's quadrature positive signal (QP2), in-phase negative signal (IN2), and quadrature negative signal (QN2) have respective phase differences of 135°, 225°, and 315° with respect to IP1.

For certain aspects, an amplifier 410 may be connected between the input signal generator 402 and the phase shifter 404. The amplifier 410 may be configured—with or without supporting circuitry—to buffer, amplify, or attenuate the input signal before being phase shifted by the phase shifter 404. The amplifier 410 may be single-ended or differential.

The ideas presented above can be extended to generate a greater number of multiphase signals, such as 12 or 16 multiphase signals. Generating more than 8 multiphase signals having the same frequency may be accomplished by incorporating more phase shifters with smaller phase shifts (e.g., more delay lines with finer delays) and more frequency dividers. For example, FIG. 4B is a block diagram of an example 16-phase signal generating circuit 450, in accordance with certain aspects of the present disclosure. The circuit 450 includes an input signal generator 402, three phase shifters 452, 453, 454, and four divide-by-2 (Div2) frequency dividers 406, 408, 456, 458. The circuit 450 may also include an amplifier 410, as described above.

The first divide-by-2 frequency divider 406 (labeled “Div2-1”) in FIG. 4B produces a first set of four signals having a frequency of f_{VCO}/2. If one signal in this first set is arbitrarily chosen as the phase reference signal 412 with a phase difference of 0°, then the other signals in the set have phase differences of 90°, 180°, and 270° with respect to the reference signal 412.

The first phase shifter 452 may be configured to shift the phase of the input signal 403 received from the input signal generator 402 by about 45° nominally to produce a first phase-shifted signal 462. The second divide-by-2 frequency divider 408 (labeled “Div2-2”) in FIG. 4B produces a second set of four signals having a frequency of f_{VCO}/2. The signals in the second set have phase differences of 22.5°, 112.5°, 202.5°, and 292.5° with respect to the reference signal 412.

The second phase shifter 453 may be configured to shift the phase of the first phase-shifted signal 462 by about 45° nominally to produce a second phase-shifted signal 464. The third divide-by-2 frequency divider 456 (labeled “Div2-3”) in FIG. 4B produces a third set of four signals having a frequency of f_{VCO}/2. The signals in the third set have phase differences of 45°, 135°, 225°, and 315° with respect to the reference signal 412.

The third phase shifter 454 may be configured to shift the phase of the second phase-shifted signal 464 by about 45° nominally to produce a third phase-shifted signal 466. The fourth divide-by-2 frequency divider 458 (labeled “Div2-4”) in FIG. 4B produces a fourth set of four signals having a frequency of f_{VCO}/2. The signals in the fourth set have phase differences of 67.5°, 157.5°, 247.5°, and 337.5° with respect to the reference signal 412. In this manner, four sets of four phase-shifted signals are generated, for a total 16 multiphase signals.

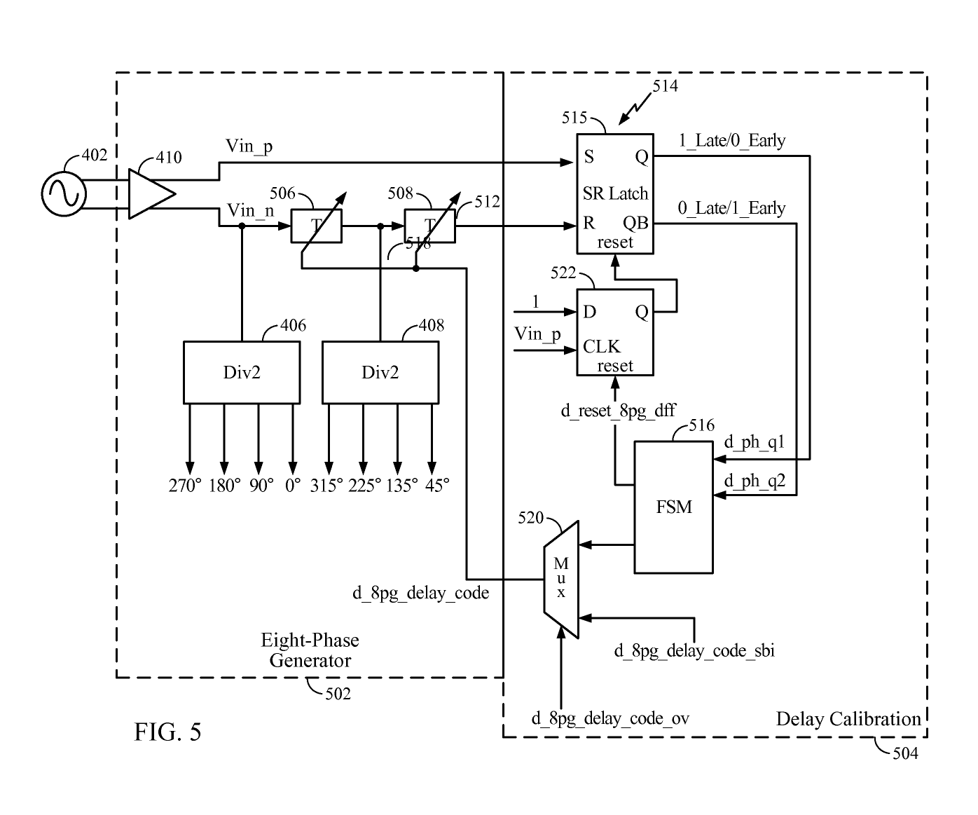

FIG. 5 is a block diagram of an example 8-phase signal generating circuit 502 and an example delay calibration circuit 504 for calibrating one or more variable delay lines 506, 508 in the 8-phase signal generating circuit, in accordance with certain aspects of the present disclosure. Such a calibration scheme ensures that each variable delay line contributes the desired amount of delay (e.g., T_{VCO}/4 in FIG. 5, which is equivalent to a 90° phase shift) at any VCO frequency or any process, voltage, and temperature (PVT) corner.

In FIG. 5, the input signal generator 402 outputs a differential oscillating signal, which may be buffered, amplified, or attenuated by an amplifier 410. The differential output signals from the amplifier 410 are the input signal 403 for the circuit 502 and are referred to as positive input voltage (Vin_p) and negative input voltage (Vin_n). Vin_p and Vin_n have a frequency of f_{VCO}, a phase difference of 180°, and are interchangeable signals, such that the operations applied to Vin_n in FIG. 5 may be applied to Vin_p instead and vice versa. Similar to the circuit 400 in FIG. 4A, the first Div2 frequency divider 406 in FIG. 5 may generate a first set of signals having a frequency of f_{VCO}/2 and phase differences of 0°, 90°, 180°, and 270° with respect to the phase reference signal 412.

The first variable delay line 506 in FIG. 5 may function as the phase shifter 404 in FIG. 4A and, hence, may shift Vin_n by nominally 90° to produce a first phase-shifted signal 510. The second Div2 frequency divider 408 in FIG. 5 may frequency divide the first phase shifted signal 510 and output a second set of signals having a frequency of f_{VCO}/2 and phase differences of 45°, 135°, 225°, and 315° with respect to the phase reference signal 412. In this manner, 8 multiphase signals are generated by the circuit 502 from the single-phase signal output by the input signal generator 402.

Since the first phase-shifted signal 510 output from the first variable delay line 506 may have a phase error from the desired phase shift, the delay calibration circuit 504 may be used to tune the first variable delay line 506 and adjust the amount of phase shift produced thereby. The delay calibration circuit 504 may include a second variable delay line 508, a bang-bang phase comparator 514, and a finite state machine (FSM) 516. The second variable delay line 508 may be cascaded with the first variable delay line 506 to phase shift the first phase-shifted signal 510 about 90° to produce a second phase-shifted signal 512. The second phase-shifted signal 512 has a total phase difference of 180° with respect to Vin_n, such that the second phase-shifted signal 512 is nearly in-phase with Vin_p.

In this manner, the bang-bang phase comparator 514 may be used to compare two signals (Vin_p and the second phase-shifted signal 512) having the same (or nearly the same) phase and determine which of the two signals has edges (e.g., rising edges) arriving first. As illustrated in FIG. 5, the bang-bang phase comparator 514 may be implemented with a set-reset (S-R) latch 515. Vin_p may be connected to the set (S) input, and the second phase-shifted signal 512 may be connected to the reset (R) input. For other aspects, the two signals may be interchanged, with corresponding logic changes where applicable in a remainder of the delay calibration circuit 504. The first output (Q) of the S-R latch 515 may output a logic HIGH (binary 1) if the second phase-shifted signal 512 has an edge arriving later than a corresponding edge of Vin_p and a logic LOW (binary 0) if the second phase-shifted signal 512 has an edge arriving earlier than that of Vin_p. The second output (QB) has the opposite logic from the first output (Q). Thus, the first and second outputs (Q and QB) of the S-R latch function as comparison signals. Acceptable values for Q-QB are 01 for early and 10 for late. Other outputs are not valid and indicate that the calibration may be stopped at this point, since the current setting of the variable delay lines 506, 508 is within the resolution of the delay calibration circuit 504.

The FSM 516 may receive one or both of the comparison signals from the bang-bang phase comparator 514. The FSM 516 may process the comparison signal(s) and make a decision to increase, decrease, or maintain a value of a variable affecting either or both of the first and second variable delay lines 506, 508. The decision may be made using a binary search algorithm, for example, using shift registers in the FSM 516 to increase or decrease the delay. The FSM 516 may control the first and/or second variable delay lines 506, 508 via a control line 518 or through a multiplexer 520 outputting to the control line 518. The multiplexer 520 may be used to override calibration by commandeering the control line 518. For certain aspects, the FSM 516 may have two separate control lines, one for each of the first and second variable delay lines 506, 508.

The delay output (Q) of a delay (D) latch 522 may be used in an effort to synchronize reset of the S-R latch 515 with the input signal (Vine) thereto, since this input signal is used as a reference signal for delay line calibration. Without this synchronization, the reset of the S-R latch 515 may happen asynchronously with respect to the reference for delay calibration. The S-R latch 515 may respond only to the first 0→1 transition (i.e., rising edge) after the reset and keep this value until the next falling edge of the reset signal. The D latch 522 may itself be reset based on an output from the FSM 516.

Calibration may be performed in a similar manner for multiphase signal generating circuits outputting a greater number of multiphase signals than 8. For example, in the 16-phase signal generating circuit 450 of FIG. 4B, a fourth phase shifter (not shown)

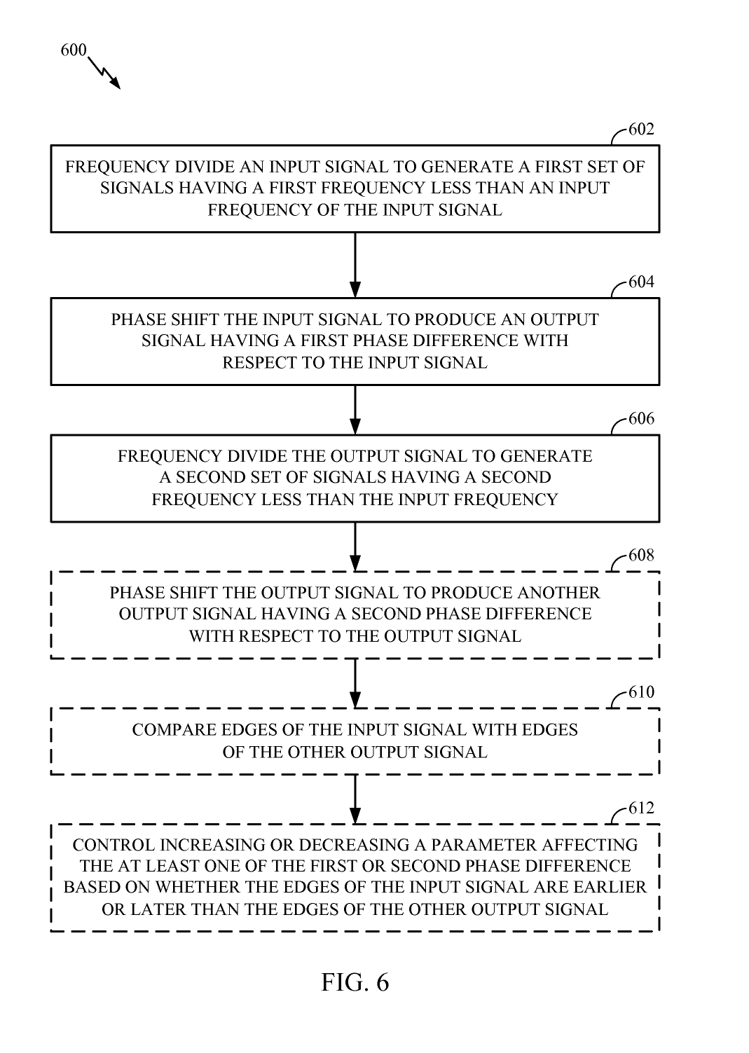

FIG. 6 illustrates example operations 600 for multiphase signal generation, according to certain aspects of the present disclosure. The operations 600 may be performed by a multiphase signal generating circuit, such as the circuits 400, 450, 502, portrayed in FIGS. 4A-5.

The operations 600 may begin, at block 602, with the multiphase generating circuit frequency dividing an input signal to generate a first set of signals having a first frequency less than an input frequency of the input signal. The signals in the first set may have different phase differences therebetween.

At block 604, the multiphase generating circuit may phase shift the input signal to produce a first output signal having a first phase difference with respect to the input signal. The phase shifting at block 604 may involve using a delay line, for example, between the input signal and the first output signal. In this case, the operations 600 may further include the multiphase generating circuit adjusting the delay line, such that the first phase difference is a variable phase difference with respect to the input signal.

At block 606, the multiphase generating circuit may frequency divide the first output signal to generate a second set of signals having a second frequency less than the input frequency. The first set of signals may have four signals, and the second set of signals may also have four signals. For certain aspects, frequency dividing the input signal and/or frequency dividing the first output signal involves frequency dividing by 2 using a frequency divide-by-2 circuit, for example.

According to certain aspects, the first frequency equals the second frequency. For certain aspects, the first frequency and the second frequency are half the input frequency.

According to certain aspects, signals in the first set have phase differences of 0°, 90°, 180°, and 270° with respect to a reference signal, the reference signal being one of the first set of signals. The signals in the second set may have phase differences of 45°, 135°, 225°, and 315° with respect to the reference signal.

According to certain aspects, the input signal is a differential signal having a positive signal and a negative signal. For certain aspects, phase shifting the input signal at block 604 entails phase shifting the positive signal. For other aspects, the multiphase generating circuit may phase shift the negative signal.

According to certain aspects, the operations 600 further include the multiphase generating circuit phase shifting the first output signal to produce a second output signal having a second phase difference with respect to the first output signal at block 608. In this case, the multiphase generating circuit may also compare edges of the input signal with edges of the second output signal at block 610 and control increasing or decreasing a parameter affecting the first and/or second phase difference(s) at block 612, based on whether the edges of the input signal are earlier or later than the edges of the second output signal.

According to certain aspects, the operations 600 further involve using at least one of the first set of signals or the second set of signals as multiphase signals in an N-path filter.

According to certain aspects, the operations 600 further involve the multiphase generating circuit determining a third frequency of an oscillating signal associated with a first voltage by using at least one of the first or second set of signals; determining a fourth frequency of the oscillating signal associated with a second voltage by using the at least one of the first or second set of signals, wherein the second voltage is different than the first voltage; and calculating a gain (e.g., k_{VCO}) based on the third frequency, the fourth frequency, the first voltage, and the second voltage. For certain aspects, determining the third frequency or the fourth frequency includes concurrently counting edges of each signal in the first and/or second set(s) of signals over a period. The oscillating signal may be the input signal.

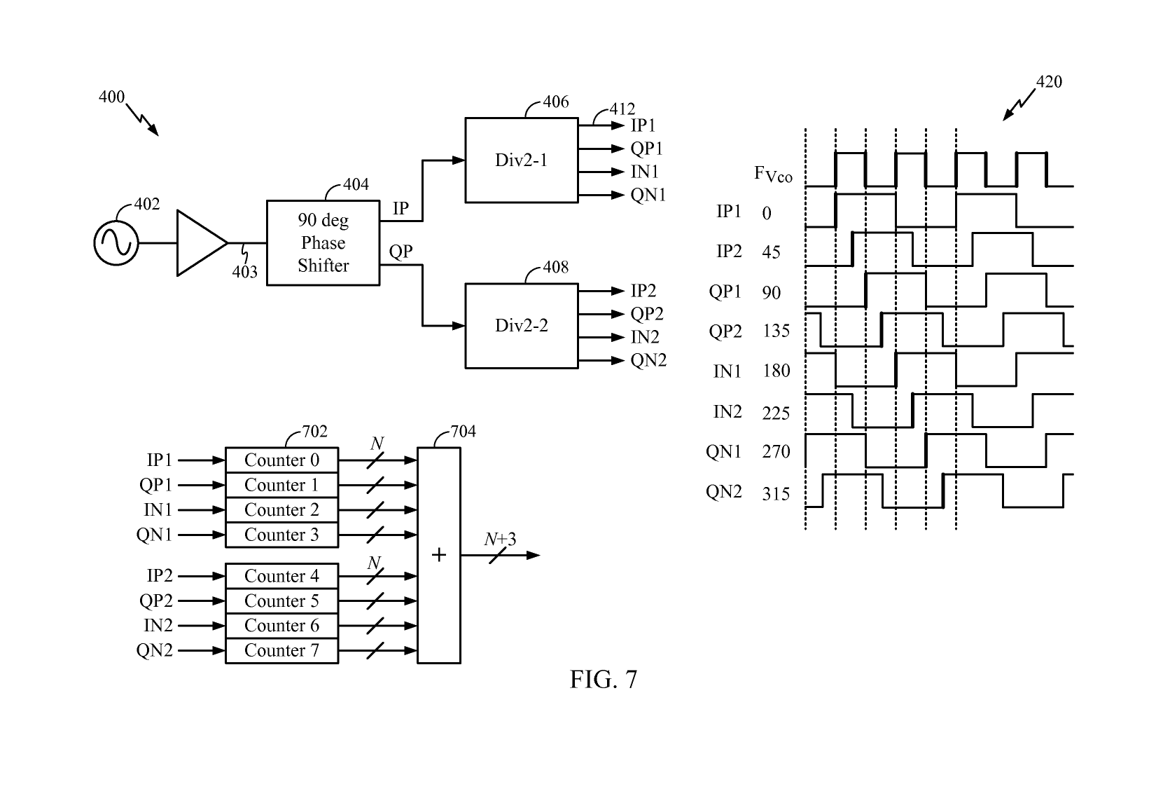

As described above, multiphase signal generation has many useful applications, such as fast frequency measurement of the input oscillating signal output by the input signal generator 402. Such fast frequency estimation may be performed by concurrently counting edges (e.g., rising edges) of the generated multiphase signals over a known period and summing the results for all signals. For example, FIG. 7 adds eight frequency counters 702 and a summer 704 to the circuit 400 of FIG. 4A to accomplish this frequency estimation, in accordance with certain aspects of the present disclosure. The total number of counted edges for all multiphase signals may then be divided by the number of multiphase signals used and by the time value of the known period to calculate an accurate frequency measurement. By counting edges of several multiphase signals at once, the frequency can be determined much faster and more accurately than counting edges of a single input oscillating signal.

Such fast frequency estimation may also be used to quickly determine a VCO gain (k_{VCO}) with high accuracy. Since a VCO outputs signals having different frequencies based on the input voltage,

$${k}_{VCO} = \frac{{f}_{2} - {f}_{1}}{{v}_{2} - {v}_{1}}$$

where f₁ is the frequency of the signal output by the VCO when the input voltage is v₁ and where f₂ is the frequency of the signal output when the input voltage is v₂. The two different input voltages may be input to the VCO, and the two output frequencies associated with the VCO input voltages may be measured using the fast, accurate frequency estimation based on multiphase signals described above. The VCO gain may be calculated based on the input voltages and their associated output frequencies.

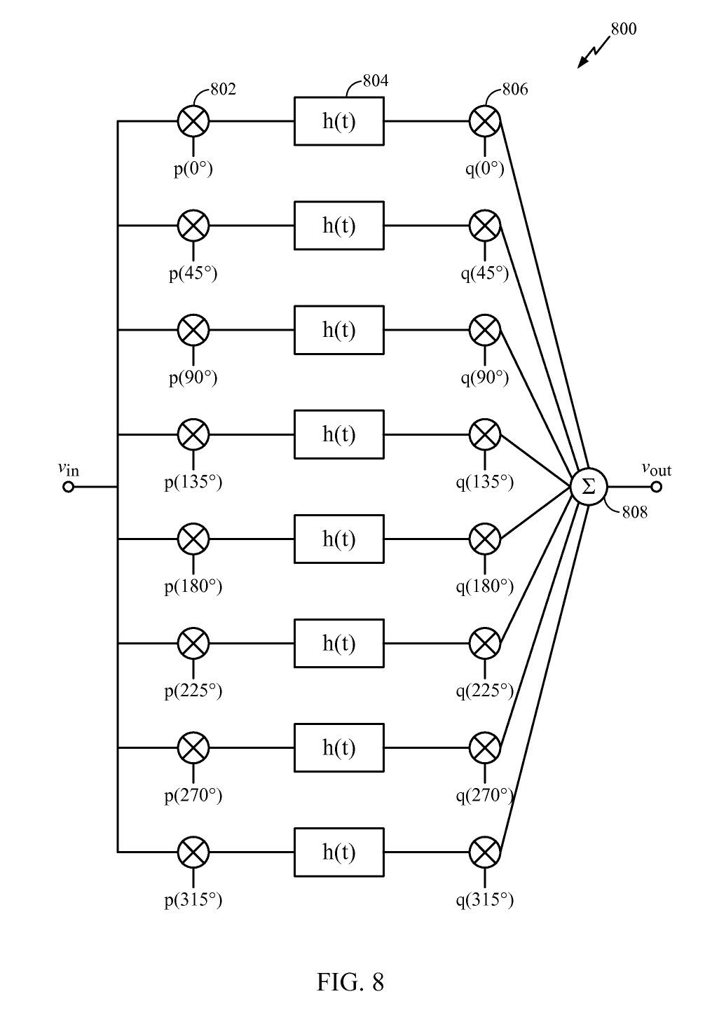

Another application for multiphase signals is in N-path filters. N-path filters may also be referred to as sampled data filters or commutated capacitors. FIG. 8 is a block diagram of an example 8-path filter 800, in accordance with certain aspects of the present disclosure. Each path in the 8-path filter 800 includes a first mixer 802, a transform function h(t) 804, and a second mixer 806. The mixers 802, 806 are driven by phase-shifted versions of the clock signals p(t) and q(t), either of which may be eight multiphase oscillating signals generated by a multiphase generating circuit, such as the circuit 400 in FIG. 4A. The outputs of the second mixers 806 are combined by a summer 808 to generate the output of the filter 800.

The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

For example, means for transmitting may comprise a transmitter (e.g., the transceiver front end 254 of the user terminal 120 depicted in FIG. 2 or the transceiver front end 222 of the access point 110 shown in FIG. 2) and/or an antenna (e.g., the antennas 252ma through 252mu of the user terminal 120m portrayed in FIG. 2 or the antennas 224a through 224ap of the access point 110 illustrated in FIG. 2). Means for receiving may comprise a receiver (e.g., the transceiver front end 254 of the user terminal 120 depicted in FIG. 2 or the transceiver front end 222 of the access point 110 shown in FIG. 2) and/or an antenna (e.g., the antennas 252ma through 252mu of the user terminal 120m portrayed in FIG. 2 or the antennas 224a through 224ap of the access point 110 illustrated in FIG. 2). Means for processing or means for determining may comprise a processing system, which may include one or more processors, such as the RX data processor 270, the TX data processor 288, and/or the controller 280 of the user terminal 120 illustrated in FIG. 2. Means for frequency dividing may include a frequency dividing circuit, such as the Div2 frequency dividers 406, 408, 456, 458 in FIG. 4B. Means for phase shifting may include a phase shifting circuit, such as the phase shifter 404 illustrated in FIG. 4, the phase shifter 452 in FIG. 4B, or the variable delay line 506 in FIG. 5.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the PHY layer. In the case of a user terminal 120 (see FIG. 1), a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC (Application Specific Integrated Circuit) with the processor, the bus interface, the user interface in the case of an access terminal), supporting circuitry, and at least a portion of the machine-readable media integrated into a single chip, or with one or more FPGAs (Field Programmable Gate Arrays), PLDs (Programmable Logic Devices), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A multiphase generating circuit, comprising:
a first phase shifting circuit configured to phase shift an input signal having an input frequency, such that an output signal of the first phase shifting circuit has a first phase difference with respect to the input signal;
a first frequency dividing circuit configured to receive the input signal and output a first set of signals having a first frequency less than the input frequency of the input signal; and
a second frequency dividing circuit configured to receive the output signal of the first phase shifting circuit and output a second set of signals having a second frequency less than the input frequency of the input signal.

2. The multiphase generating circuit of claim 1, wherein the first frequency equals the second frequency.

3. The multiphase generating circuit of claim 2, wherein the first frequency and the second frequency are half the input frequency.

4. The multiphase generating circuit of claim 1, wherein the first phase shifting circuit comprises a delay line.

5. The multiphase generating circuit of claim 4, wherein the delay line is adjustable, such that the first phase difference is a variable phase difference with respect to the input signal.

6. The multiphase generating circuit of claim 1, wherein at least one of the first frequency dividing circuit or the second frequency dividing circuit comprises a frequency divide-by-2 circuit.

7. The multiphase generating circuit of claim 1, wherein signals in the first set have phase differences of 0°, 90°, 180°, and 270° with respect to a reference signal, the reference signal being one of the first set of signals, and wherein signals in the second set have phase differences of 45°, 135°, 225°, and 315° with respect to the reference signal.

8. The multiphase generating circuit of claim 1, wherein the multiphase generating circuit comprises an 8-phase generating circuit.

9. The multiphase generating circuit of claim 1, wherein the input signal comprises a differential signal having a positive signal and a negative signal and wherein the first phase shifting circuit is configured to phase shift the negative signal.

10. The multiphase generating circuit of claim 1, further comprising a second phase shifting circuit configured to phase shift the output signal of the first phase shifting circuit, such that an output signal of the second phase shifting circuit has a second phase difference with respect to the output signal of the first phase shifting circuit.

11. The multiphase generating circuit of claim 10, wherein the second phase shifting circuit comprises an adjustable delay line, such that the second phase difference is a variable phase difference with respect to the output signal of the first phase shifting circuit.

12. The multiphase generating circuit of claim 10, wherein a sum of the first phase difference and the second phase difference is nominally 180°.

13. The multiphase generating circuit of claim 10, further comprising a calibration circuit configured to:
receive the input signal and the output signal of the second phase shifting circuit; and
adjust at least one of the first or second phase difference based on relative timing of the input signal and the output signal of the second phase shifting circuit.

14. The multiphase generating circuit of claim 13, wherein the calibration circuit comprises:
a phase comparator configured to:
compare edges of the input signal with edges of the output signal of the second phase shifting circuit; and
output a comparison signal indicating whether the edges of the input signal are earlier or later than the edges of the output signal of the second phase shifting circuit; and
a finite state machine configured to:
receive the comparison signal; and
control increasing or decreasing a parameter affecting the at least one of the first or second phase difference based on the comparison signal.

15. The multiphase generating circuit of claim 1, wherein the first phase difference is nominally 90°.

16. The multiphase generating circuit of claim 1, further comprising:
a second phase shifting circuit configured to phase shift the output signal of the first phase shifting circuit, such that an output signal of the second phase shifting circuit has a second phase difference with respect to the output signal of the first phase shifting circuit; and
a third frequency dividing circuit configured to receive the output signal of the second phase shifting circuit and output a third set of signals having a third frequency less than the input frequency of the input signal.

17. The multiphase generating circuit of claim 16, further comprising:
a third phase shifting circuit configured to phase shift the output signal of the second phase shifting circuit, such that an output signal of the third phase shifting circuit has a third phase difference with respect to the output signal of the second phase shifting circuit; and
a fourth frequency dividing circuit configured to receive the output signal of the third phase shifting circuit and output a fourth set of signals having a fourth frequency less than the input frequency of the input signal.

18. A method for multiphase signal generation, comprising:
frequency dividing an input signal to generate a first set of signals having a first frequency less than an input frequency of the input signal;
phase shifting the input signal to produce a first output signal having a first phase difference with respect to the input signal; and
frequency dividing the first output signal to generate a second set of signals having a second frequency less than the input frequency.

19. The method of claim 18, wherein signals in the first set have different phase differences therebetween.

20. The method of claim 18, wherein the first frequency equals the second frequency.

21. The method of claim 20, wherein the first frequency and the second frequency are half the input frequency.

22. The method of claim 18, wherein the phase shifting comprises using a delay line between the input signal and the first output signal.

23. The method of claim 22, further comprising adjusting the delay line, such that the first phase difference is a variable phase difference with respect to the input signal.

24. The method of claim 18, wherein at least one of frequency dividing the input signal or frequency dividing the first output signal comprises frequency dividing by 2 using a frequency divide-by-2 circuit.

25. The method of claim 18, wherein the input signal comprises a differential signal having a positive signal and a negative signal and wherein phase shifting the input signal comprises phase shifting the positive signal.

26. The method of claim 18, further comprising phase shifting the first output signal to produce a second output signal having a second phase difference with respect to the first output signal.

27. The method of claim 26, further comprising:
comparing edges of the input signal with edges of the second output signal; and
controlling increasing or decreasing a parameter affecting the at least one of the first or second phase difference based on whether the edges of the input signal are earlier or later than the edges of the second output signal.

28. The method of claim 18, further comprising using at least one of the first set of signals or the second set of signals as multiphase signals in an N-path filter.

29. The method of claim 18, further comprising:
determining a third frequency of an oscillating signal associated with a first voltage by using at least one of the first or second set of signals;
determining a fourth frequency of the oscillating signal associated with a second voltage by using the at least one of the first or second set of signals, wherein the second voltage is different than the first voltage; and
calculating a gain based on the third frequency, the fourth frequency, the first voltage, and the second voltage.

30. The method of claim 29, wherein determining the third frequency or the fourth frequency comprises concurrently counting edges of each signal in the at least one of the first or second set of signals over a period.
